(19) United States
(12) Patent Application Publication
(10) Pub. No.: US 2026/0251695 A1
(43) Pub. Date: Aug. 27, 2026

(54) A CIRCUIT OF DETECTING A FAULT OF A POWER SOURCE, METHOD AND SYSTEM, ELECTRONIC DEVICE, AND NON-TRANSITORY READABLE STORAGE MEDIUM

(71) Applicant: SUZHOU METABRAIN INTELLIGENT TECHNOLOGY CO., LTD., Suzhou, Jiangsu (CN)

(72) Inventors: Tao LIU, Suzhou, Jiangsu (CN); Jian WANG, Suzhou, Jiangsu (CN); Cai KONG, Suzhou, Jiangsu (CN)

(73) Assignee: SUZHOU METABRAIN INTELLIGENT TECHNOLOGY CO., LTD., Suzhou, Jiangsu (CN)

(21) Appl. No.: 18/879,223

(22) PCT Filed: Nov. 20, 2023
(86) PCT No.: PCT/CN2023/132732

§ 371 Date: Dec. 26, 2024

(30) Foreign Application Priority Data
Feb. 9, 2023 (CN) 202310087115.8

(51) Int. Cl. G01R 31/28; G01R 31/52

(52) U.S. Cl. CPC G01R 31/2836; G01R 31/52

(57) ABSTRACT

A circuit of detecting a fault of a power source, method and system, an electronic device and a non-transitory readable storage medium, which relate to the technical field of detecting a fault in a power source. The circuit of detecting a fault of a power source comprises a main controller (101) and a power conversion chip (102), the main controller (101) being electrically connected to the power conversion chip (102); wherein the power conversion chip (102) is configured to send a current sense signal and a temperature sense signal to the main controller (101); and the main controller (101) is configured to determine a fault type corresponding to the power conversion chip (102) according to the current sense signal and the temperature sense signal. This improves the power source detection efficiency and detection accuracy.

### CROSS-REFERENCE TO RELATED APPLICATION

The present disclosure claims priority to Chinese Patent Application No. 202310087115.8, filed to the China National Intellectual Property Administration on Feb. 9, 2023 and entitled “Power source Fault Detection Circuit, Method and System, Electronic Device, and Storage Medium”, which is incorporated herein by reference in its entirety.

### TECHNICAL FIELD

The present disclosure relates to the technical field of detecting a fault of a power source, and in particular, to a circuit of detecting a fault of a power source, method and system, an electronic device, and a non-transitory readable storage medium.

### BACKGROUND

With the increase of power consumption of various devices in a server, current specifications during normal operation of the server are also higher and higher. The power supply capability of a single power source cannot meet current requirements of these devices, and an architecture for supplying power by a multi-phase power source needs to be used, that is, a plurality of single-phase power sources are used in parallel to improve the current output capability, thereby ensuring normal operation of the server by using power supply stability of the multi-phase power source.

A main control chip of an existing multi-phase power source has fault early warning and fault protection functions. When a fault occurs in a line, for example, fault situations of anomalous power supply or no power supply, the main control chip may turn off the power source according to a fault signal, so as to prevent the fault from continuing to spread. However, currently, when fault detection is performed on the multi-phase power source, it is only possible to determine whether a fault exists currently, and the actual fault type thereof cannot be judged. The actual fault type needs to be judged manually, for example, by observing whether components in a power stage are damaged or by means of instrument measurement, etc., and thus the detection efficiency and detection accuracy are relatively low.

### SUMMARY

Regarding the problems existing in the related art, some embodiments of the present disclosure provide a circuit of detecting a fault of a power source, method and system, an electronic device, and a non-transitory readable storage medium.

Some embodiments of the present disclosure provide a circuit of detecting a fault of a power source, comprising a main controller and a power conversion chip, the main controller being electrically connected to the power conversion chip; wherein
the power conversion chip is configured to send a current sense signal and a temperature sense signal to the main controller; and
the main controller is configured to determine a fault type corresponding to the power conversion chip according to the current sense signal and the temperature sense signal.

According to the circuit of detecting a fault of a power source provided in some embodiments of the present disclosure, the main controller is connected to a plurality of the power conversion chips, the main controller comprises one temperature sense pin and a plurality of current sense pins, and each power conversion chip of the plurality of power conversion chips comprises a current sense signal output end and a temperature sense signal output end; wherein
the current sense signal output end of the each power conversion chip is connected in parallel with corresponding one current sense pin of the plurality of current sense pins on the main controller, respectively; and
the temperature sense signal output end of the each power conversion chip is connected to one same circuit node, and the same circuit node is connected to the temperature sense pin on the main controller.

According to the circuit of detecting a fault of a power source provided in some embodiments of the present disclosure, the main controller comprises a first fault alarm unit, a second fault alarm unit, a third fault alarm unit, and a fourth fault alarm unit; wherein
the first fault alarm unit is configured to determine the fault type as an under voltage fault when the current sense signal is a 0 V level signal and the temperature sense signal is a 0 V level signal;
the second fault alarm unit is configured to determine the fault type as an over current fault when the current sense signal is a 0 V level signal and the temperature sense signal is a first preset drive level signal;
the third fault alarm unit is configured to determine the fault type as an over temperature fault when the current sense signal is a second preset drive level signal and the temperature sense signal is a 0 V level signal; and
the fourth fault alarm unit is configured to determine the fault type as a short-circuit fault when the current sense signal is the second preset drive level signal and the temperature sense signal is the first preset drive level signal.

According to the circuit of detecting a fault of a power source provided in some embodiments of the present disclosure, the main controller further comprises a multi-phase power source fault location unit, configured to perform fault location operation on a faulty power conversion chip in the plurality of power conversion chips according to the current sense signal sent by the current sense signal output end of the each power conversion chip.

According to the circuit of detecting a fault of a power source provided in some embodiments of the present disclosure, the multi-phase power source fault location unit is configured to: when the main controller determines that there is the faulty power conversion chip in the plurality of power conversion chips, determines a power conversion chip corresponding to each current sense signal on the basis of a connection relationship between each current sense pin in the plurality of current sense pins and the current sense signal output end of corresponding one power conversion chip in the plurality of power conversion chips, and performs the fault location operation on the faulty power conversion chip in the plurality of power conversion chips according to the connection relationship and a current sense fault signal, wherein the current sense fault signal is a current sense signal sent by the faulty power conversion chip.

According to the circuit of detecting a fault of a power source provided in some embodiments of the present disclosure, the circuit of detecting a fault of a power source fault further comprises a short-circuit protection sub-circuit, an input end of the short-circuit protection sub-circuit is connected to a power-supplying source, and an output end of the short-circuit protection sub-circuit is connected to the each power conversion chip; wherein
the short-circuit protection sub-circuit is configured to disconnect, when any one of the plurality of power conversion chips fails, the power-supplying source from the each power conversion chip.

According to the circuit of detecting a fault of a power source provided in some embodiments of the present disclosure, the short-circuit protection sub-circuit comprises an Efuse module and a plurality of NAND gates, wherein each NAND gate in the plurality of NAND gates is connected to corresponding one power conversion chip in the plurality of power conversion chips, and an output end of the each NAND gate is connected to one same enable port of the Efuse module; wherein
a first input end of the each NAND gate is connected to the current sense signal output end of the corresponding one power conversion chip, and a second input end of the each NAND gate is connected to the temperature sense signal output end of the corresponding one power conversion chip, and the NAND gate is configured to generate a short-circuit protection signal when it is determined that a short-circuit fault exists in any one of the plurality of power conversion chips, and send the short-circuit protection signal to the same enable port of the Efuse module, to disconnect the power-supplying source from the each power conversion chip.

According to the circuit of detecting a fault of a power source provided in some embodiments of the present disclosure, the main controller is further configured to generate corresponding alarm signals according to different fault types; wherein the alarm signals comprise an under voltage fault alarm signal, an over current fault alarm signal, an over temperature fault alarm signal, and a short-circuit fault alarm signal.

According to the circuit of detecting a fault of a power source provided in some embodiments of the present disclosure, the main controller is further configured to determine that the one power conversion chip in the plurality of power conversion chips has no fault when a level signal of the current sense signal and a level signal of the temperature sense signal are greater than the 0 V level signal, and the level signal of the current sense signal is less than the second preset drive level signal and the level signal of the temperature sense signal is less than the first preset drive level signal.

Some embodiments of the present disclosure further provide a method of detecting a fault in a power source based on the circuit of detecting a fault of a power source according to any one above, comprising:
a current sense signal sent by a current sense signal output end of a power conversion chip is acquired;
a temperature sense signal sent by a temperature sense signal output end of the power conversion chip is acquired; and
a fault type corresponding to the power conversion chip is determined according to the current sense signal and the temperature sense signal.

According to the method of detecting a fault in a power source provided in some embodiments of the present disclosure, a current sense signal sent by a current sense signal output end of a power conversion chip is acquired, comprises:

The current sense signals sent by the current sense signal output ends of each power conversion chip of a plurality of power conversion chips are acquired; and
wherein a fault type corresponding to the power conversion chip is determined according to the current sense signal and the temperature sense signal, comprises:
the fault type of the each power conversion chip in the plurality of power conversion chips is determined according to the current sense signal sent by the current sense signal output end of the each power conversion chip and the temperature sense signal sent by the temperature sense signal output end of the each power conversion chip.

According to the method of detecting a fault in a power source provided in some embodiments of the present disclosure, the fault type of the each power conversion chip in the plurality of power conversion chips is determined according to the current sense signal sent by the current sense signal output end of the each power conversion chip and the temperature sense signal sent by the temperature sense signal output end of the each power conversion chip, comprises:
whether the each power conversion chip has a fault is judged according to the current sense signal sent by the current sense signal output end of the each power conversion chip and the temperature sense signal sent by the temperature sense signal output end of the each power conversion chip; if the current sense signal sent by the current sense signal output end of the one power conversion chip is a 0 V level signal and the temperature sense signal sent by the temperature sense signal output end of the one power conversion chip is a 0 V level signal, it is determined that the one power conversion chip in the plurality of power conversion chips has an under voltage fault;
if the current sense signal sent by the current sense signal output end of the one power conversion chip is a 0 V level signal and the temperature sense signal sent by the temperature sense signal output end of the one power conversion chip is a first preset drive level signal, it is determined that the one power conversion chip has an over current fault;
if the current sense signal sent by the current sense signal output end of the one power conversion chip is a second preset drive level signal and the temperature sense signal sent by the temperature sense signal output end of the one power conversion chip is a 0 V level signal, it is determined that the one power conversion chip has an over temperature fault; and
if the current sense signal sent by the current sense signal output end of the one power conversion chip is the second preset drive level signal and the temperature sense signal sent by the temperature sense signal output end of the one power conversion chip is the first preset drive level signal, it is determined that the one power conversion chip has a short-circuit fault.

According to the method of detecting a fault in a power source provided in some embodiments of the present disclosure, the method further comprises:
when it is determined that there is a faulty power conversion chip in the plurality of power conversion chips, according to the current sense signal output end corresponding to each current sense signal, fault location operation on the faulty power conversion chip is performed.

According to the method of detecting a fault in a power source provided in some embodiments of the present disclosure, when it is determined that there is a faulty power conversion chip in the plurality of power conversion chips, according to the current sense signal output end corresponding to each current sense signal, fault location operation on the faulty power conversion chip is performed, comprises:
a power conversion chip corresponding to each current sense signal is determined on the basis of a connection relationship between each current sense pin in the plurality of current sense pins and the current sense signal output end of corresponding one power conversion chip in the plurality of power conversion chips; and
the fault location operation on the faulty power conversion chip in the plurality of power conversion chips is performed according to the connection relationship and a current sense fault signal, wherein the current sense fault signal is a current sense signal sent by the faulty power conversion chip.

According to the method of detecting a fault in a power source provided in some embodiments of the present disclosure, the method further comprises:
a fault protection enable signal is generated when the one power conversion chip has a fault; and
the each power conversion chip is disconnected from a power-supplying source on the basis of the fault protection enable signal.

According to the method of detecting a fault in a power source provided in some embodiments of the present disclosure, the method further comprises:
when a short-circuit fault occurs in the one power conversion chip, on the basis of NAND gates respectively connected to the each power conversion chip, a short-circuit protection signal is generated according to a target current sense signal and the temperature sense signal sent by the temperature sense signal output end of the one power conversion chip; wherein the target current sense signal is the current sense signal sent by the current sense signal output end of the one power conversion chip having the short-circuit fault; and
the each power conversion chip is disconnected from the power-supplying source by the short-circuit protection signal.

According to the method of detecting a fault in a power source provided in some embodiments of the present disclosure, a fault type corresponding to the power conversion chip is determined according to the current sense signal and the temperature sense signal, further comprises:
it is determined that the power conversion chip has no fault when a level signal of the current sense signal and a level signal of the temperature sense signal are greater than the 0 V level signal, and the level signal of the current sense signal is less than the second preset drive level signal and the level signal of the temperature sense signal is less than the first preset drive level signal.

Some embodiments of the present disclosure further provide a system of detecting a fault in a power source, comprising:
a first signal collection module, configured to acquire a current sense signal sent by a current sense signal output end of a power conversion chip;
a second signal collection module, configured to acquire a temperature sense signal sent by a temperature sense signal output end of the power conversion chip; and
a power source fault detection module, configured to determine a fault type corresponding to the power conversion chip according to the current sense signal and the temperature sense signal.

Some embodiments of the present disclosure further provide an electronic device, comprising a memory, a processor and a computer program stored on the memory and executable on the processor, wherein when the processor executes the program, any one of the method of detecting a fault in a power source fault is implemented.

Some embodiments of the present disclosure further provide a non-transitory readable storage medium, storing a computer program, which when executed by a processor, implements any one of the method of detecting a fault in a power source as described above.

In the circuit of detecting a fault of a power source, method and system, electronic device, and non-transitory readable storage medium provided in some embodiments of the present disclosure, the current sense signal sent by the current sense signal output end and the temperature sense signal sent by the temperature sense signal output end on the power conversion chip are respectively acquired by the current sense pin and the temperature sense pin of the main controller, and then the fault type corresponding to the power conversion chip is determined according to the status change situations of the two signals, thereby improving the power source detection efficiency and detection accuracy.

### BRIEF DESCRIPTION OF THE DRAWINGS

In order to describe the technical solutions in some embodiments of the present disclosure or in the related art more clearly, hereinafter, accompanying drawings requiring to be used in the embodiments or the related art will be introduced briefly. Apparently, the accompanying drawings in the following description merely relate to some embodiments of the present disclosure, and for a person of ordinary skill in the art, other accompanying drawings can also be obtained according to these accompanying drawings without involving any inventive effort.

FIG. 1 is a schematic structural diagram of a circuit of detecting a fault of a power source provided according to some embodiments of the present disclosure;

FIG. 2 is a schematic diagram of an overall structure of a circuit of detecting a fault of a power source provided according to some embodiments of the present disclosure;

FIG. 3 is a schematic diagram of an overall structure of a circuit of detecting a fault of a power source provided according to some other embodiments of the present disclosure;

FIG. 4 is a schematic flowchart of a method of detecting a fault in a power source provided according to some embodiments of the present disclosure;

FIG. 5 is a schematic structural diagram of a system of detecting a fault in a power source provided according to some embodiments of the present disclosure; and

FIG. 6 is a schematic structural diagram of an electronic device provided according to some embodiments of the present disclosure.

### DESCRIPTION OF REFERENCE SIGNS

101: Main controller; 102: Power conversion chip; 1011: Current sense pin;
1012: Temperature sense pin; 1021: Current sense signal output end;
1022: Temperature sense signal output end; 201: Main control chip;
202: Power conversion chip; 203: Efuse module; 301: Main control chip;
302: Power conversion chip; 303: Efuse module; 304: NAND gate;
601: Processor; 602: Communication interface; 603: Memory; 604: Communication bus.

### DETAILED DESCRIPTION OF THE EMBODIMENTS

To make the objects, technical solutions and advantages of some embodiments of the present disclosure clearer, hereinafter, the technical solutions in some embodiments of the present disclosure will be described clearly and thoroughly in combination with the accompanying drawings in some embodiments of the present disclosure. Obviously, the embodiments as described are only some rather than all the embodiments of the present disclosure. All other embodiments obtained by a person of ordinary skill in the art on the basis of the embodiments of the present disclosure without involving any inventive effort shall all fall within the scope of protection of the present disclosure.

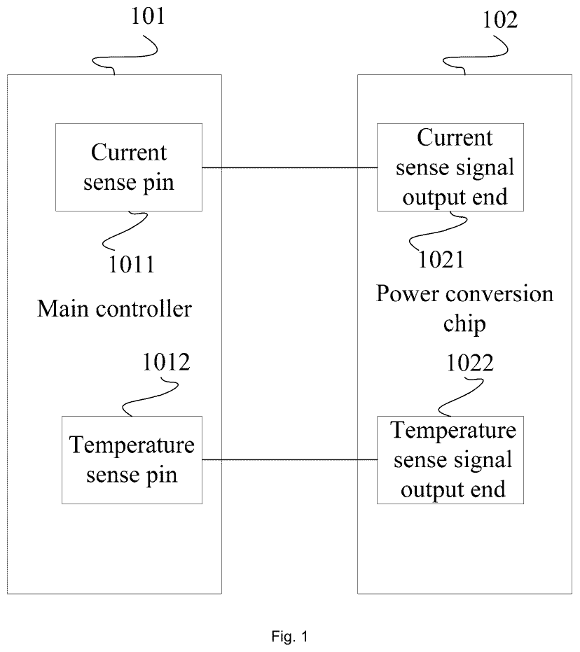

FIG. 1 is a schematic structural diagram of a circuit of detecting a fault of a power source provided according to some embodiments of the present disclosure. As shown in FIG. 1, some embodiments of the present disclosure provide a circuit of detecting a fault of a power source, comprising a main controller 101 and a power conversion chip 102, the main controller 101 being electrically connected to the power conversion chip 102, the main controller 101 comprises a current sense pin 1011 and a temperature sense pin 1012, and the power conversion chip 102 comprises a current sense signal output end 1021 and a temperature sense signal output end 1022; wherein
the current sense pin 1011 is connected to the current sense signal output end 1021, and the temperature sense pin 1012 is connected to the temperature sense signal output end 1022;
the power conversion chip 102 is configured to send a current sense signal and a temperature sense signal to the main controller 101; and
the main controller 101 is configured to determine a fault type corresponding to the power conversion chip 102 according to the current sense signal sent by the current sense signal output end 1021 and the temperature sense signal sent by the temperature sense signal output end 1022.

In some embodiments of the present disclosure, a Power Stage (PS for short) is the power conversion chip 102, and a single PS is a single-phase power source. The main controller 101 comprises a main control chip, which outputs an Enable (EN for short) signal and a Pulse Width Modulation (PWM for short) signal to control output voltage and current signals of the PS; wherein the EN signal outputted by the main control chip is used for enabling operation of the PS; and by adjusting different frequencies and duty ratios, the PWM signal can control the magnitudes of output voltage and output current.

Optionally, the current sense signal output end 1021 of the power conversion chip 102 outputs an Isense signal, i.e. the current sense signal, which can feed back the magnitude of the output current of the PS; and the temperature sense signal output end 1022 of the power conversion chip 102 outputs a Tsense signal, i.e. the temperature sense signal, which can feed back temperature information of the PS. According to some embodiments of the present disclosure, the temperature sense signal and the current sense signal fed back by the power conversion chip 102 are acquired, and then fault judgment and fault-type identification are performed on the power conversion chip 102 according to the change situations of the two detection signals, which achieves improved fault detection efficiency and accuracy compared with the existing methods of determining a fault type manually.

Regarding the circuit of detecting a fault of a power source provided in some embodiments of the present disclosure, the current sense signal sent by the current sense signal output end and the temperature sense signal sent by the temperature sense signal output end on the power conversion chip are respectively acquired by the current sense pin and the temperature sense pin of the main controller, and then the fault type corresponding to the power conversion chip is determined according to the status change situations of the two signals, thereby improving the power source detection efficiency and detection accuracy.

On the basis of the described embodiments, the main controller is connected to a plurality of the power conversion chips, the main controller comprises one temperature sense pin and a plurality of current sense pins, and each power conversion chip of the plurality of power conversion chips comprises a current sense signal output end and a temperature sense signal output end; wherein
the current sense signal output end of the each power conversion chip is connected in parallel with corresponding one current sense pin of the plurality of current sense pins on the main controller, respectively; and
the temperature sense signal output end of the each power conversion chip is connected to one same circuit node, and the same circuit node is connected to the temperature sense pin on the main controller.

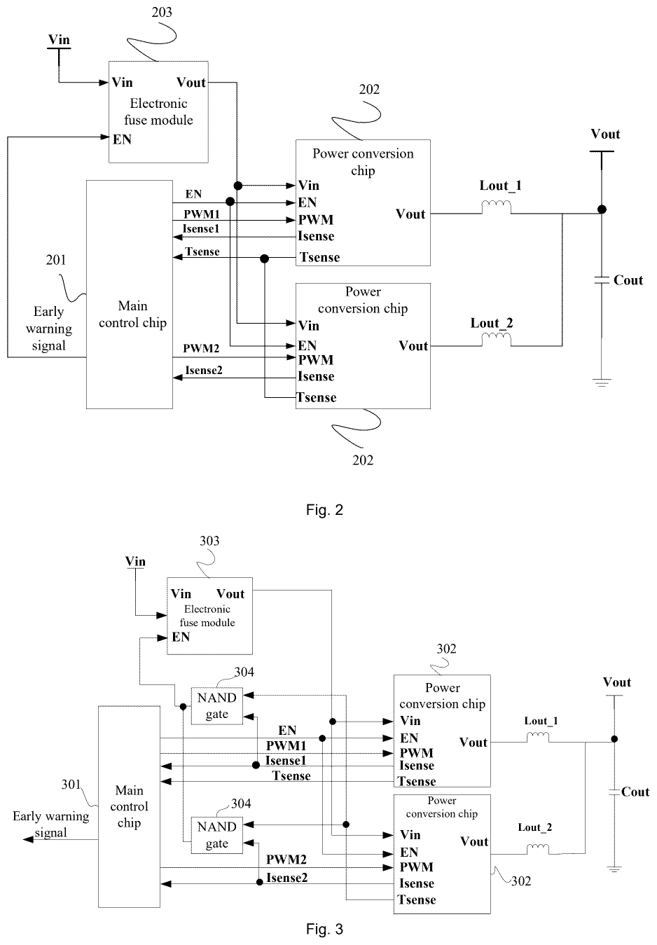

Due to the effect of size and process of the main control chip, currently, the main control chip generally has only one pin (temperature sense pin) for monitoring the temperature information. FIG. 2 is a schematic diagram of an overall structure of a circuit of detecting a fault of a power source provided according to some embodiments of the present disclosure. As shown in FIG. 2, when multiple phases are used in parallel, in some embodiments of the present disclosure, a Tsense pin of each PS, i.e. a temperature sense signal output end, is connected to the same circuit node, to be jointly connected to a temperature sense pin on a main control chip; wherein a Tsense signal is a voltage signal, and the voltage value thereof is directly proportional to the temperature of the PS. When multiple phases are used in parallel, the main control chip 201 acquires a PS having the highest temperature value among all PSs. Optionally, a current sense signal output end of each power conversion chip 202 is connected to respective current sense pin on the main control chip 201, that is, a Isense pin of each power conversion chip 202 sends respective corresponding Isense signal to a corresponding current sense pin on the main control chip 201, so as to ensure that each current sense pin is connected to one current sense signal output end, such that the main control chip 201 can locate a faulty power conversion chip according to current sense signals fed back by different power conversion chips 202; then, according to detected change situations of the current sense signal and temperature sense signal, and on the basis of a preset fault-type judgment condition, a fault type of the power conversion chip 202 is determined.

On the basis of the described embodiments, the main controller comprises a first fault alarm unit, a second fault alarm unit, a third fault alarm unit, and a fourth fault alarm unit; wherein
the first fault alarm unit is configured to determine the fault type as an under voltage fault when the current sense signal is a 0 V level signal and the temperature sense signal is a 0 V level signal;
the second fault alarm unit is configured to determine the fault type as an over current fault when the current sense signal is a 0 V level signal and the temperature sense signal is a first preset drive level signal;
the third fault alarm unit is configured to determine the fault type as an over temperature fault when the current sense signal is a second preset drive level signal and the temperature sense signal is a 0 V level signal; and
the fourth fault alarm unit is configured to determine the fault type as a short-circuit fault when the current sense signal is the second preset drive level signal and the temperature sense signal is the first preset drive level signal.

With regard to a solution of supplying power by a single-phase power source or a solution of supplying power by a multi-phase power source, in some embodiments of the present disclosure, fault-type identification can be performed on the power conversion chips by means of the main controller. Optionally, in some embodiments, as shown in FIG. 2, in the existing solution of supplying power by a multi-phase power source, an output end of the Isense signal of each power conversion chip 202 is separately connected to one current sense pin on the main control chip 201, and multiple phases of Tsense signals are connected together and then transmitted to the main control chip 201. Therefore, a fault early warning function of each phase of power source can be achieved by using state changes of the Isense signal and the Tsense signal in coordination.

Optionally, taking a CPU as an example for illustration, currently, when a multi-phase power source used by the CPU (Central Processing Unit) operates normally, in addition to EN and Vin signals, a VCC (Volt Current Condenser, a power supply voltage) drive level (generally 3.3 V or 5 V) is further needed. Therefore, in some embodiments of the present disclosure, the values corresponding to the first preset drive level signal and the second preset drive level signal can be determined according to elements in the circuit (such as CPU and GPU (graphics processing unit)), and the first preset drive level and the second preset drive level have the same value.

On the basis of the described embodiments, the main controller is further configured to determine that the one power conversion chip in the plurality of power conversion chips has no fault when a level signal of the current sense signal and a level signal of the temperature sense signal are greater than the 0 V level signal, and the level signal of the current sense signal is less than the second preset drive level signal and the level signal of the temperature sense signal is less than the first preset drive level signal.

In some embodiments of the present disclosure, fault detection is performed on the multi-phase power source by the main control chip in the main controller; and when the levels of the Isense signal and the Tsense signal are higher than 0 V and lower than a drive level VCC of the power conversion chip, the multi-phase power source is in a normal operation state at this time, and the main controller does not give a fault alarm.

Optionally, when voltage states of the Isense signal and the Tsense signal change, fault detection can be performed on a single-phase power source according to a combination relationship of voltage states of the two signals under different faults. Table 1 shows fault types and detection modes provided in some embodiments of the present disclosure, as shown in Table 1:

TABLE 1

| | Isense | Tsense |
|---|---|---|
| Fault type | signal state | signal state |
| UVLO | 0 V | 0 V |
| OCP | 0 V | VCC |
| OTP | VCC | 0 V |
| Short | VCC | VCC |
| circuit | | |

When the main control chip detects that the Isense signal is 0 V and the Tsense signal is 0 V, it is judged that an input under voltage fault (Under Voltage Lock Out, UVLO for short) occurs in the phase of power source; when the main control chip detects that the Isense signal is 0 V and the Tsense signal is at the first preset drive level VCC, it is judged that an over current fault (Over Current Protection, OCP for short) occurs in the phase of power source; when the main control chip detects that the Isense signal is at the second preset drive level VCC and the Tsense signal is 0 V, it is judged that an over temperature fault (Over Temp Protection, OTP for short) occurs in the phase of power source; and when the main control chip detects that the Isense signal is at the second preset drive level VCC and the Tsense signal is at the first preset drive level VCC, it is judged that a short-circuit fault (for example, an upper-most short-circuit fault) occurs in the phase of power source.

On the basis of the described embodiments, the main controller further comprises a multi-phase power source fault location unit, configured to perform fault location operation on a faulty power conversion chip in the plurality of power conversion chips according to the current sense signal sent by the current sense signal output end of the each power conversion chip.

In some embodiments of the present disclosure, according to the source of a faulty current sense signal, it is determined that a faulty power conversion chip exists, and then a fault area thereof is located.

On the basis of the described embodiments, the multi-phase power source fault location unit is configured to: when the main controller determines that there is the faulty power conversion chip in the plurality of power conversion chips, determines a power conversion chip corresponding to each current sense signal on the basis of a connection relationship between each current sense pin in the plurality of current sense pins and the current sense signal output end of corresponding one power conversion chip in the plurality of power conversion chips, and performs the fault location operation on the faulty power conversion chip in the plurality of power conversion chips according to the connection relationship and a current sense fault signal, wherein the current sense fault signal is a current sense signal sent by the faulty power conversion chip.

Currently, when a main control chip of a multi-phase power source performs fault early warning and fault protection, when faults such as over current, over voltage, under voltage and over temperature occur in a line, a fault early warning signal will be sent, and a PS is turned off by stopping outputting a PWM signal, so as to prevent the fault from continuing to spread; however, the early warning cannot reflect which phase of power source has a fault. Taking over temperature protection as an example, currently, Tsense signals of all phases are connected together and are uniformly monitored by the main controller, and therefore temperature information of each power conversion chip cannot be learnt. When over temperature occurs in any one phase of power source, a Tsense voltage signal on an entire parallel path is increased; after acquiring that the Tsense voltage reaches a set level threshold, the main controller determines that a fault exists, but the main controller can only identify that an over temperature fault exists, but cannot accurately locate which phase the fault belongs to. Thus, it is not beneficial for fault analysis. Likewise, for faults such as over voltage, under voltage and upper-mos short-circuit of the multi-phase power source, the existing detecting a fault in a power source also cannot locate an actual fault area.

With regard to the described problems, in some embodiments of the present disclosure, the main control chip in the main controller acquires the current sense signal sent by each power conversion chip, and as shown in FIG. 2, after acquiring the current sense signal, the main control chip 201 may determine a power conversion chip 202 corresponding to each current sense signal according to a connection relationship between the current sense pins and the current sense signal output ends. Optionally, the main control chip 201 judges which phase of power conversion chip 201 has a fault according to the current sense signal of each phase of power conversion chip 202 and the temperature sense signal acquired by the temperature sense pin, and then judges which phase of power conversion chip fails according to the source of the faulty current sense signal (i.e. the current sense signal output end corresponding to the current sense signal), thereby quickly locating a fault area.

On the basis of the described embodiments, the circuit of detecting a fault of a power source further comprises a short-circuit protection sub-circuit, an input end of the short-circuit protection sub-circuit is connected to a power-supplying source, and an output end of the short-circuit protection sub-circuit is connected to the each power conversion chip; wherein
the short-circuit protection sub-circuit is configured to disconnect, when any one of the plurality of power conversion chips fails, the power-supplying source from the each power conversion chip.

Currently, fault early warning is that the main controller sends a fault early warning after detecting fault information of the PS, and an time interval from the discovery of the fault to the sending of the fault early warning signal is at a ms level. When a fault occurs, in order to prevent elements on the circuit from being damaged, an input voltage Vin of the power conversion chip needs to be turned off in time; for example, when a power conversion chip has an upper-mos short-circuit fault, the input voltage Vin may be directly connected to an output Vout; wherein the Vout supplies power to the CPU or GPU, and a Vin power source is generally 12 V. If the 12 V voltage is directly applied to the CPU, the CPU may be damaged due to over voltage. Since the main controller cannot disconnect input of the Vin signal, when a short-circuit fault occurs, the CPU may be damaged.

In view of the problem above, in some embodiments of the present disclosure, as shown in FIG. 2, a short-circuit protection sub-circuit is provided in the circuit of detecting a fault of a power source, and the short-circuit protection sub-circuit comprises an Efuse module 203. By connecting a fault signal generated by the main control chip 201 to an Enable signal of the Efuse module 203 of a Vin power supply path, when a short-circuit fault (or other faults) occurs, the fault signal is sent to one same enable port of the Efuse module 203, so that the Enable signal of the Efuse module 203 is pulled down, and the Efuse module 203 is disconnected, thereby realizing short-circuit protection.

On the basis of the described embodiments, the short-circuit protection sub-circuit comprises an Efuse module and a plurality of NAND gates, wherein each NAND gate in the plurality of NAND gates is connected to corresponding one power conversion chip in the plurality of power conversion chips, and an output end of the each NAND gate is connected to one same enable port of the Efuse module; wherein
a first input end of the each NAND gate is connected to the current sense signal output end of the corresponding one power conversion chip, and a second input end of the each NAND gate is connected to the temperature sense signal output end of the corresponding one power conversion chip, and the NAND gate is configured to generate a short-circuit protection signal when it is determined that a short-circuit fault exists in any one of the plurality of power conversion chips, and send the short-circuit protection signal to the same enable port of the Efuse module, to disconnect the power-supplying source from the each power conversion chip.

In some embodiments of the present disclosure, as shown in FIG. 2, a time interval from the circuit of detecting a fault of a power source detecting a fault to the main control chip 201 sending a fault early warning signal is at a ms level. However, for the short-circuit situation of the power conversion chip 202, the delay will most likely damage the CPU, and therefore the fault response speed needs to be increased. FIG. 3 is a schematic diagram of an overall structure of a circuit of detecting a fault of a power source provided according to some other embodiments of the present disclosure. As shown in FIG. 3, for an upper-mos short-circuit fault, the circuit of detecting a fault of a power source structure may be used to achieve faster protection, and the response speed thereof is at a ns level. Optionally, in some embodiments of the present disclosure, Isense signals and Tsense signals of a multi-phase power source are connected to an Enable signal port of an Efuse module 303 through NAND gates 304. For each NAND gate 304, when receiving a signal having a voltage of 0 V, the signal is judged as a low-level signal, and when receiving a signal at a preset drive level VCC, the signal is judged as a high-level signal. As shown in FIG. 3, when the upper-mos short-circuit fault occurs on a certain power conversion chip 302, Isense and Tsense signals are both at the preset drive level VCC, i.e. high-level signals; at this time, output of the NAND gate 304 is at a low level, and at the same time, the Efuse module 303 is pulled down due to an Enable signal, and output of the Efuse module 303 is disconnected. Therefore, short-circuit protection can be implemented more quickly. It should be noted that, in some embodiments of the present disclosure, a fault early warning signal outputted by a main control chip 301 may also be connected to the same enable port (not shown in FIG. 3) of the Efuse module 303. For fault types other than the short-circuit fault, the main control chip 301 directly sends a fault early warning signal to the Efuse module 303, so as to achieve over voltage protection, over temperature protection, and over current protection of the circuit.

On the basis of the described embodiments, a main controller is further configured to generate corresponding alarm signals according to different fault types; wherein the alarm signals comprise an under voltage fault alarm signal, an over current fault alarm signal, an over temperature fault alarm signal, and a short-circuit fault alarm signal.

In some embodiments of the present disclosure, the main controller is further configured to generate, after determining that a power conversion chip has a fault, alarm signals corresponding to different fault types according to the fault type and the fault early warning signal. For example, alarms of different fault types can be achieved by different acousto-optic combination devices (a buzzer, a light-emitting diode, etc., for example, the light-emitting diode uses indicator lights of different colors to generate a fault-type alarm).

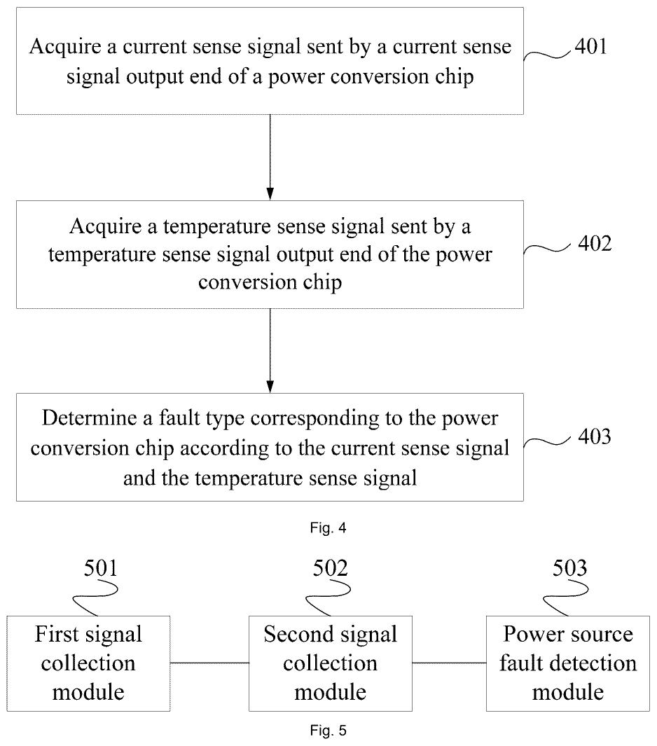

FIG. 4 is a schematic flowchart of a method of detecting a fault in a power source provided according to some embodiments of the present disclosure. As shown in FIG. 4, some embodiments of the present disclosure provide a method of detecting a fault in a power source based on the circuit of detecting a fault of a power source in the described embodiments, comprising:
step 401: a current sense signal sent by a current sense signal output end of a power conversion chip is acquired;
step 402: a temperature sense signal sent by a temperature sense signal output end of the power conversion chip is acquired; and
step 403: a fault type corresponding to the power conversion chip is determined according to the current sense signal and the temperature sense signal.

In some embodiments of the present disclosure, a main controller in the circuit of detecting a fault of a power source is taken as an execution subject for illustration. The main controller acquires the temperature sense signal sent by the current sense signal output end and the current sense signal sent by the current sense signal output end of the power conversion chip, and then performs fault judgment and fault-type identification on the power conversion chip according to the change situations of the two detection signals on the basis of fault types corresponding to pre-constructed state-type combination modes of current sense signals and temperature sense signals; wherein the fault type comprises over temperature fault, over current fault, over voltage fault, and short-circuit fault, which achieves improved fault detection efficiency and accuracy compared with the existing methods of determining a fault type manually.

Regarding the method of detecting a fault in a power source provided in some embodiments of the present disclosure, the current sense signal sent by the current sense signal output end and the temperature sense signal sent by the temperature sense signal output end on the power conversion chip are respectively acquired by the current sense pin and the temperature sense pin of the main controller, and then the fault type corresponding to the power conversion chip is determined according to the status change situations of the two signals, thereby improving the power source detection efficiency and detection accuracy.

On the basis of the described embodiments, a current sense signal sent by a current sense signal output end of a power conversion chip is acquired, comprises:
the current sense signals sent by the current sense signal output ends of each power conversion chip of a plurality of power conversion chips are acquired; and
wherein the fault type corresponding to the power conversion chip is determined according to the current sense signal and the temperature sense signal, comprises:
the fault type of the each power conversion chip in the plurality of power conversion chips is determined according to the current sense signal sent by the current sense signal output end of the each power conversion chip and the temperature sense signal sent by the temperature sense signal output end of the each power conversion chip.

In some embodiments of the present disclosure, for fault detection of a multi-phase power source, a Tsense pin of each power conversion chip is connected to one temperature sense pin on a main control chip; and the current sense signal output end of each power conversion chip is connected to each current sense pin of the main control chip on the main controller, that is, a Isense pin of each power conversion chip sends its corresponding Isense signal to the corresponding current sense pin on the main control chip, so as to ensure that each current sense pin is connected to one current sense signal output end.

Optionally, the main control chip can locate a faulty power conversion chip according to current sense signals fed back by different power conversion chips; then, according to detected change situations of the current sense signal and temperature sense signal, and on the basis of a preset fault-type judgment condition, a fault type of the power conversion chip is determined.

On the basis of the described embodiments, the fault type of the each power conversion chip in the plurality of power conversion chips is determined according to the current sense signal sent by the current sense signal output end of the each power conversion chip and the temperature sense signal sent by the temperature sense signal output end of the each power conversion chip, comprises:
whether the each power conversion chip has a fault is judged according to the current sense signal sent by the current sense signal output end of the each power conversion chip and the temperature sense signal sent by the temperature sense signal output end of the each power conversion chip; if the current sense signal sent by the current sense signal output end of the one power conversion chip is a 0 V level signal and the temperature sense signal sent by the temperature sense signal output end of the one power conversion chip is a 0 V level signal, it is determined that the one power conversion chip in the plurality of power conversion chips has an under voltage fault;
if the current sense signal sent by the current sense signal output end of the one power conversion chip is a 0 V level signal and the temperature sense signal sent by the temperature sense signal output end of the one power conversion chip is a first preset drive level signal, it is determined that the one power conversion chip has an over current fault;
if the current sense signal sent by the current sense signal output end of the one power conversion chip is a second preset drive level signal and the temperature sense signal sent by the temperature sense signal output end of the one power conversion chip is a 0 V level signal, it is determined that the one power conversion chip has an over temperature fault; and
if the current sense signal sent by the current sense signal output end of the one power conversion chip is the second preset drive level signal and the temperature sense signal sent by the temperature sense signal output end of the one power conversion chip is the first preset drive level signal, it is determined that the one power conversion chip has a short-circuit fault.

In some embodiments of the present disclosure, the main controller implements fault detection of the power conversion chip according to voltage states of the current sense signal and the temperature sense signal at the current moment. Optionally, an output end of the Isense signal of each power conversion chip is separately connected to one current sense pin on the main control chip, and multiple phases of the Tsense signals are connected together and then transmitted to the main control chip (regarding fault detection of a multi-phase power source). Therefore, a fault early warning function of each phase of power source can be achieved by using state changes of the Isense signal and the Tsense signal in coordination.

Optionally, a preset drive level is set. A CPU is taken as an example for illustration. Currently, when a multi-phase power source used by a CPU operates normally, in addition to EN and Vin signals, a VCC drive level is generally 3.3 V or 5 V. If a level signal of the current sense signal and a level signal of the temperature sense signal are greater than the 0 V level signal, and the level signal of the current sense signal is less than the second preset drive level signal and the level signal of the temperature sense signal is less than the first preset drive level signal (in some embodiments of the present disclosure, the first preset drive level signal and the second preset drive level signal are set as the same value, e.g. 3.3 V), it is determined that the power conversion chip has no fault.

In some embodiments of the present disclosure, fault detection is performed on the multi-phase power source by the main control chip in the main controller; and when a level of the Isense signal and a level of the Tsense signal are higher than 0 V, and the level of the Isense signal is lower than a drive level VCC of the power conversion chip, and the level of the Tsense signal is lower than a drive level VCC of the power conversion chip the multi-phase power source is in a normal operation state at this time, and the main controller does not give a fault alarm.

Optionally, when voltage states of the Isense signal and the Tsense signal change, fault detection can be performed on a single-phase power source according to a combination relationship of voltage states of the two signals under different faults.

On the basis of the described embodiments, the method further comprises:
when it is determined that there is a faulty power conversion chip in the plurality of power conversion chips, according to the current sense signal output end corresponding to each current sense signal, fault location operation on the faulty power conversion chip is performed.

Optionally, when it is determined that there is a faulty power conversion chip in the plurality of power conversion chips, according to the current sense signal output end corresponding to each current sense signal, fault location operation on the faulty power conversion chip is performed, comprises:
a power conversion chip corresponding to each current sense signal is determined on the basis of a connection relationship between each current sense pin in the plurality of current sense pins and the current sense signal output end of corresponding one power conversion chip in the plurality of power conversion chips; and
the fault location operation on the faulty power conversion chip in the plurality of power conversion chips is performed according to the connection relationship and a current sense fault signal, wherein the current sense fault signal is a current sense signal sent by the faulty power conversion chip.

In some embodiments of the present disclosure, the current sense signal sent by each power conversion chip is acquired by the main control chip in the main controller. After the main control chip acquires the current sense signal, the power conversion chip corresponding to each current sense signal is determined on the basis of the connection relationship between the current sense pins and the current sense signal output ends.

Optionally, the main control chip judges which phase of power conversion chip has a fault according to the current sense signal of each phase of power conversion chip and the temperature sense signal acquired by the temperature sense pin, and then judges which phase of power conversion chip fails according to the source of a faulty current sense signal, i.e. the current sense signal output end corresponding to the current sense signal, thereby quickly locating a fault area.

On the basis of the described embodiments, the method further comprises:
a fault protection enable signal is generated when the one power conversion chip has a fault; and
the each power conversion chip is disconnected from a power-supplying source on the basis of the fault protection enable signal.

In some embodiments of the present disclosure, a short-circuit protection sub-circuit is provided in the circuit of detecting a fault of a power source, and the short-circuit protection sub-circuit is provided between Vin and the power conversion chip, and comprises an Efuse module. When a power conversion chip has a fault, the main control chip generates a fault signal, and sends the fault signal to one same enable port of the Efuse module, thereby pulling down an Enable signal of the Efuse module, so that the Efuse module is disconnected, thereby achieving power source fault protection.

On the basis of the described embodiments, the method further comprises:
when a short-circuit fault occurs in the one power conversion chip, on the basis of NAND gates respectively connected to the each power conversion chip, a short-circuit protection signal is generated according to a target current sense signal and the temperature sense signal sent by the temperature sense signal output end of the one power conversion chip; wherein the target current sense signal is the current sense signal sent by the current sense signal output end of the one power conversion chip having the short-circuit fault; and
the each power conversion chip is disconnected from the power-supplying source by the short-circuit protection signal.

In some embodiments of the present disclosure, a time interval from the circuit of detecting a fault of a power source detecting a fault to the main controller sending a fault early warning signal is at a ms level. However, for the short-circuit situation of the power conversion chip, the delay will most likely damage the CPU, and therefore the fault response speed needs to be increased. An upper-mos (Metal-Oxide-Semiconductor Field-Effect Transistor) short-circuit fault in the power conversion chip is used for illustration, in which in order to increase the response speed to an ns level, in some embodiments of the present disclosure, Isense signals and Tsense signals of a multi-phase power source are connected to the Enable signal port of the Efuse (electronic fuse) module through NAND gates. For each NAND gate, when receiving a signal having a voltage of 0 V, the signal is judged as a low-level signal, and when receiving a signal at a preset drive level VCC, the signal is judged as a high-level signal. Therefore, when the upper-mos short-circuit fault occurs on a certain power conversion chip, Isense and Tsense signals are both at the preset drive levels VCC, i.e. high-level signals; at this time, output of the NAND gate is at a low level, and at the same time, the Efuse module is pulled down due to an Enable signal, and output of the Efuse module is disconnected. Therefore, short-circuit protection can be implemented more quickly.

Hereinafter, a system of detecting a fault in a power source provided in some embodiments of the present disclosure will be described. For the system of detecting a fault in a power source described below and the method of detecting a fault in a power source as described above, reference may be made to each other.

FIG. 5 is a schematic structural diagram of a system of detecting a fault in a power source provided according to some embodiments of the present disclosure. As shown in FIG. 5, some embodiments of the present disclosure provide a system of detecting a fault in a power source, comprising a first signal collection module 501, a second signal collection module 502, and a power source fault detection module 503; wherein the first signal collection module 501 is configured to acquire a current sense signal sent by a current sense signal output end of a power conversion chip; the second signal collection module 502 is configured to acquire a temperature sense signal sent by a temperature sense signal output end of the power conversion chip; and the power source fault detection module 503 is configured to determine a fault type corresponding to the power conversion chip according to the current sense signal and the temperature sense signal.

In some embodiments of the present disclosure, the first signal collection module 501 is used to acquire the current sense signal sent by the current sense signal output end of the power conversion chip; and the second signal collection module 502 is used to acquire the temperature sense signal sent by the temperature sense signal output end of the power conversion chip. Optionally, according to the change situations of the temperature sense signal and the current sense signal, the power source fault detection module 503 performs fault judgment and fault-type identification on the power conversion chip on the basis of fault types corresponding to pre-constructed state-type combination modes of current sense signals and temperature sense signals; wherein the fault type comprises over temperature fault, over current fault, over voltage fault, and short-circuit fault, which achieves improved fault detection efficiency and accuracy compared with the existing methods of determining a fault type manually.

Regarding the system of detecting a fault in a power source provided in some embodiments of the present disclosure, the current sense signal sent by the current sense signal output end and the temperature sense signal sent by the temperature sense signal output end on the power conversion chip are respectively acquired by the current sense pin and the temperature sense pin of the main controller, and then the fault type corresponding to the power conversion chip is determined according to the status change situations of the two signals, thereby improving the power source detection efficiency and detection accuracy.

The system provided in some embodiments of the present disclosure is used to execute the method embodiments as described above, and reference may be made to the described embodiments for the flow and details, and they will not be repeated herein.

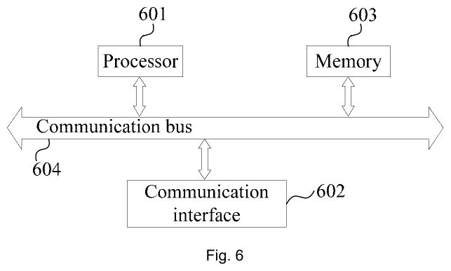

FIG. 6 is a schematic structural diagram of an electronic device provided according to some embodiments of the present disclosure. As shown in FIG. 6, the electronic device may comprise: a Processor 601, a Communications Interface 602, a Memory 603, and a communications bus 604; wherein the processor 601, the communications interface 602 and the memory 603 communicate with each other via the communications bus 604. The processor 601 can invoke logic instructions in the memory 603 to execute the method of detecting a fault in a power source, and the method comprises: a current sense signal sent by a current sense signal output end of a power conversion chip is acquired; a temperature sense signal sent by a temperature sense signal output end of the power conversion chip is acquired; and a fault type corresponding to the power conversion chip is determined according to the current sense signal and the temperature sense signal.

In addition, when the logic instructions in the memory 603 can be implemented in the form of a software functional unit and sold or used as an independent product, the logic instructions may be stored in a non-transitory storage medium. On the basis of such understanding, the part of the technical solutions of some embodiments of the present disclosure that contributes in essence or to the related art or part of the technical solutions may be embodied in the form of a software product; the computer software product is stored in a non-transitory readable storage medium and comprises several instructions to enable a computer device (which may be a personal computer, a server or a network device, etc.) to execute all or some of the steps of the method described in various embodiments of the present disclosure. Moreover, the non-transitory readable storage medium above comprises: media such as a USB flash disk, a mobile hard disk, a Read-Only Memory (ROM), a Random Access Memory (RAM), a magnetic disk, or an optical disk, and the like which can store program codes.

Some embodiments of the present disclosure further provide a computer program product, comprising a computer program stored on a non-transitory readable storage medium, wherein the computer program comprises program instructions which execute, when executed by a computer, cause the computer to execute the method of detecting a fault in a power source provided by the method as described above. The method comprises: a current sense signal sent by a current sense signal output end of a power conversion chip is acquired; a temperature sense signal sent by a temperature sense signal output end of the power conversion chip is acquired; and a fault type corresponding to the power conversion chip is determined according to the current sense signal and the temperature sense signal.

In still another aspect, some embodiments of the present disclosure further provide a non-transitory readable storage medium, storing a computer program, which when executed by a processor, implements the method of detecting a fault in a power source provided by the embodiments as described above. The method comprises: a current sense signal sent by a current sense signal output end of a power conversion chip is acquired; a temperature sense signal sent by a temperature sense signal output end of the power conversion chip is acquired; and a fault type corresponding to the power conversion chip is determined according to the current sense signal and the temperature sense signal.

The apparatus embodiments as described above are merely exemplary. Units described as separate components may or may not be physically separated, and the components displayed as units may or may not be physical modules, that is, may be located in one place, or may be distributed in a plurality of network units. Some or all of the modules may be selected according to actual needs to achieve the purpose of the solutions of the embodiments. A person of ordinary skill in the art would understand and implement the embodiments without any inventive effort.

From the description of the described embodiments, a person skilled in the art would have been able to clearly understand that the embodiments may be implemented by using software and necessary general hardware platforms, and of course may also be implemented using hardware. On the basis of such understanding, the portion of the technical solutions that contributes in essence or contributes to the related art may be embodied in the form of a software product; the computer software product is stored in a non-transitory readable storage medium (such as an ROM/RAM, a magnetic disk and an optical disc), and comprises several instructions to cause a computer device (which may be a personal computer, a server or a network device, etc.) to execute the method in various embodiments or the method in certain parts of the embodiments in the present disclosure.

Finally, it should be noted that the embodiments above are only used to illustrate rather than limit the technical solutions of some embodiments the present disclosure. Although some embodiments the present disclosure have been explained in detail with reference to the embodiments above, a person of ordinary skill in the art would have understood: they still could modify the technical solutions disclosed in the described embodiments or make equivalent replacements to some technical features therein. Moreover, these modifications or replacements shall not render that the nature of the corresponding technical solutions departs from the spirit and scope of the technical solutions in various embodiments of the present disclosure.

1. A circuit of detecting a fault of a power source, comprising a main controller and a power conversion chip, the main controller being electrically connected to the power conversion chip; wherein
the power conversion chip is configured to send a current sense signal and a temperature sense signal to the main controller; and
the main controller is configured to determine a fault type corresponding to the power conversion chip according to the current sense signal and the temperature sense signal.

2. The circuit according to claim 1, wherein the main controller is connected to a plurality of power conversion chips, the main controller comprises one temperature sense pin and a plurality of current sense pins, and each power conversion chip of the plurality of power conversion chips comprises a current sense signal output end and a temperature sense signal output end; wherein
the current sense signal output end of the each power conversion chip is connected in parallel with corresponding one current sense pin of the plurality of current sense pins on the main controller, respectively; and
the temperature sense signal output end of the each power conversion chip is connected to one same circuit node, and the same circuit node is connected to the temperature sense pin on the main controller.

3. The circuit according to claim 2, wherein the main controller comprises a first fault alarm unit, a second fault alarm unit, a third fault alarm unit, and a fourth fault alarm unit; wherein
the first fault alarm unit is configured to determine the fault type as an under voltage fault when the current sense signal is a 0 V level signal and the temperature sense signal is a 0 V level signal;
the second fault alarm unit is configured to determine the fault type as an over current fault when the current sense signal is a 0 V level signal and the temperature sense signal is a first preset drive level signal;
the third fault alarm unit is configured to determine the fault type as an over temperature fault when the current sense signal is a second preset drive level signal and the temperature sense signal is a 0 V level signal; and
the fourth fault alarm unit is configured to determine the fault type as a short-circuit fault when the current sense signal is the second preset drive level signal and the temperature sense signal is the first preset drive level signal.

4. The circuit according to claim 2, wherein the main controller further comprises a multi-phase power source fault location unit, configured to perform fault location operation on a faulty power conversion chip in the plurality of power conversion chips according to the current sense signal sent by the current sense signal output end of the each power conversion chip.

5. The circuit according to claim 4, wherein the multi-phase power source fault location unit is configured to, when the main controller determines that there is the faulty power conversion chip in the plurality of power conversion chips, determine a power conversion chip corresponding to each current sense signal on the basis of a connection relationship between each current sense pin in the plurality of current sense pins and the current sense signal output end of corresponding one power conversion chip in the plurality of power conversion chips, and perform the fault location operation on the faulty power conversion chip in the plurality of power conversion chips according to the connection relationship and a current sense fault signal, wherein the current sense fault signal is a current sense signal sent by the faulty power conversion chip.

6. The circuit according to claim 3, wherein the circuit further comprises a short-circuit protection sub-circuit, an input end of the short-circuit protection sub-circuit is connected to a power-supplying source, and an output end of the short-circuit protection sub-circuit is connected to the each power conversion chip;
the short-circuit protection sub-circuit is configured to disconnect, when any one of the plurality of power conversion chips fails, the power-supplying source from the each power conversion chip.

7. The circuit according to claim 6, wherein the short-circuit protection sub-circuit comprises an Efuse module and a plurality of NAND gates, wherein each NAND gate in the plurality of NAND gates is connected to corresponding one power conversion chip in the plurality of power conversion chips, and an output end of the each NAND gate is connected to one same enable port of the Efuse module;
a first input end of the each NAND gate is connected to the current sense signal output end of the corresponding one power conversion chip, and a second input end of the each NAND gate is connected to the temperature sense signal output end of the corresponding one power conversion chip, and the NAND gate is configured to generate a short-circuit protection signal when it is determined that a short-circuit fault exists in any one of the plurality of power conversion chips, and send the short-circuit protection signal to the same enable port of the Efuse module, to disconnect the power-supplying source from the each power conversion chip.

8. The circuit according to claim 3, wherein the main controller is further configured to generate corresponding alarm signals according to different fault types; wherein the alarm signals comprise an under voltage fault alarm signal, an over current fault alarm signal, an over temperature fault alarm signal, and a short-circuit fault alarm signal.

9. The circuit according to claim 3, wherein the main controller is further configured to determine that the one power conversion chip in the plurality of power conversion chips has no fault when a level signal of the current sense signal and a level signal of the temperature sense signal are greater than the 0 V level signal, and the level signal of the current sense signal is less than the second preset drive level signal and the level signal of the temperature sense signal is less than the first preset drive level signal.

10. A method of detecting a fault of a power source based on the circuit according to claim 1, comprising:
acquiring a current sense signal sent by a current sense signal output end of a power conversion chip;
acquiring a temperature sense signal sent by a temperature sense signal output end of the power conversion chip; and
determining a fault type corresponding to the power conversion chip according to the current sense signal and the temperature sense signal.

11. The method according to claim 10, wherein the acquiring a current sense signal sent by a current sense signal output end of a power conversion chip, comprises:
acquiring the current sense signal sent by the current sense signal output end of each power conversion chip of a plurality of power conversion chips; and
wherein determining a fault type corresponding to the power conversion chip according to the current sense signal and the temperature sense signal, comprises:
determining the fault type of the each power conversion chip in the plurality of power conversion chips according to the current sense signal sent by the current sense signal output end of the each power conversion chip and the temperature sense signal sent by the temperature sense signal output end of the each power conversion chip.

12. The method according to claim 11, wherein determining the fault type of the each power conversion chip in the plurality of power conversion chips according to the current sense signal sent by the current sense signal output end of the each power conversion chip and the temperature sense signal sent by the temperature sense signal output end of the each power conversion chip, comprises:
judging whether the each power conversion chip has a fault according to the current sense signal sent by the current sense signal output end of the each power conversion chip and the temperature sense signal sent by the temperature sense signal output end of the each power conversion chip;
determining that one power conversion chip in the plurality of power conversion chips has an under voltage fault if the current sense signal sent by the current sense signal output end of the one power conversion chip is a 0 V level signal and the temperature sense signal sent by the temperature sense signal output end of the one power conversion chip is a 0 V level signal;
determining that the one power conversion chip has an over current fault if the current sense signal sent by the current sense signal output end of the one power conversion chip is a 0 V level signal and the temperature sense signal sent by the temperature sense signal output end of the one power conversion chip is a first preset drive level signal;
determining that the one power conversion chip has an over temperature fault if the current sense signal sent by the current sense signal output end of the one power conversion chip is a second preset drive level signal and the temperature sense signal sent by the temperature sense signal output end of the one power conversion chip is a 0 V level signal; and
determining that the one power conversion chip has a short-circuit fault if the current sense signal sent by the current sense signal output end of the one power conversion chip is the second preset drive level signal and the temperature sense signal sent by the temperature sense signal output end of the one power conversion chip is the first preset drive level signal.

13. The method according to claim 11, wherein the method further comprises:
when it is determined that there is a faulty power conversion chip in the plurality of power conversion chips, according to the current sense signal output end corresponding to each current sense signal, performing fault location operation on the faulty power conversion chip.

14. The method according to claim 13, wherein when it is determined that there is a faulty power conversion chip in the plurality of power conversion chips, according to the current sense signal output end corresponding to each current sense signal, performing fault location operation on the faulty power conversion chip, comprises:
determining a power conversion chip corresponding to each current sense signal on the basis of a connection relationship between each current sense pin in the plurality of current sense pins and the current sense signal output end of corresponding one power conversion chip in the plurality of power conversion chips; and
performing the fault location operation on the faulty power conversion chip in the plurality of power conversion chips according to the connection relationship and a current sense fault signal, wherein the current sense fault signal is a current sense signal sent by the faulty power conversion chip.

15. The method according to claim 12, wherein the method further comprises:
generating a fault protection enable signal when the one power conversion chip has a fault; and
disconnecting the each power conversion chip from a power-supplying source on the basis of the fault protection enable signal.

16. The method according to claim 15, wherein the method further comprises:
when a short-circuit fault occurs in the one power conversion chip, on the basis of NAND gates respectively connected to the each power conversion chip, generating a short-circuit protection signal according to a target current sense signal and the temperature sense signal sent by the temperature sense signal output end of the one power conversion chip; wherein the target current sense signal is the current sense signal sent by the current sense signal output end of the one power conversion chip; and
disconnecting the each power conversion chip from the power-supplying source by the short-circuit protection signal.

17. The method according to claim 12, wherein the determining the fault type of the each power conversion chip in the plurality of power conversion chips according to the current sense signal sent by the current sense signal output end of the each power conversion chip and the temperature sense signal sent by the temperature sense signal output end of the each power conversion chip, further comprises:
determining that the power conversion chip has no fault when a level signal of the current sense signal and a level signal of the temperature sense signal are greater than the 0 V level signal, the level signal of the current sense signal is less than the second preset drive level signal and the level signal of the temperature sense signal is less than the first preset drive level signal.

18. (canceled)

19. An electronic device, comprising a memory, a processor, and a computer program stored on the memory and executable on the processor, wherein the processor implements the method of detecting a fault of a power source according to claim 10 when executing the computer program.

20. A non-transitory readable storage medium having a computer program stored thereon, wherein the computer program, when executed by a processor, implements the method of detecting a fault of a power source according to claim 10.

21. A method of detecting a fault of a power source based on the circuit according to claim 2, comprising:
acquiring a current sense signal sent by a current sense signal output end of a power conversion chip;
acquiring a temperature sense signal sent by a temperature sense signal output end of the power conversion chip; and
determining a fault type corresponding to the power conversion chip according to the current sense signal and the temperature sense signal.
